(19) United States
(12) Patent Application Publication
(10) Pub. No.: US 2012/0074957 A1
(43) Pub. Date: Mar. 29, 2012

(54) DEVICE AND METHOD FOR PROCESSING AND MEASURING PROPERTIES OF A MOVING ROD OF MATERIAL

(75) Inventor: Dierk SCHROEDER, Hamburg (DE)

(73) Assignee: HAUNI MASCHINENBAU AG, Hamburg (DE)

(21) Appl. No.: 13/241,950

(22) Filed: Sep. 23, 2011

(30) Foreign Application Priority Data
Sep. 28, 2010 (DE) 10 2010 041 572.3

(51) Int. Cl. G01R 27/04

(52) U.S. Cl. 324/636

(57) ABSTRACT

Device and method for processing and measuring properties of a moving rod of tobacco processing industry. Device includes a microwave measurement device in which endless rod is conveyable through microwave resonator from input side to output side. Microwave generator is included to generate a measurement signal having output frequency f₀ and to supply measurement signal to input side of microwave resonator. At least one analysis arrangement includes a mixer, a low-pass filter, and an analog-to-digital converter in series, and local oscillator to generate a signal with local frequency f_{LO}. Mixer is connected to port of microwave resonator and to output of local oscillator to generate difference signal of frequency f_{IM}, which is less than f₀ and corresponds to a difference of frequencies f₀ and f_{LO}. Low-pass filter is structured to pass output signal of mixer with intermediate frequency f_{IM}, and filter higher frequency signal portions.

### CROSS-REFERENCE TO RELATED APPLICATIONS

The present application claims priority under 35 U.S.C. §119(a) of German Patent Application No. 10 2010 041 572.3 filed Sep. 28, 2010, the disclosure of which is expressly incorporated by reference herein in its entirety.

### BACKGROUND OF THE INVENTION

1. Field of the Invention

The invention relates to a device for processing and measuring properties of a moving rod of material in the tobacco processing industry. The device includes a microwave measurement device, which has a microwave resonator through which the rod of material is conveyed or can be conveyed. On an input side, the microwave resonator is supplied or can be supplied with a measurement signal generated by a microwave generator having an output frequency f₀. The invention relates further to a corresponding microwave measurement device and a method for processing and measuring properties of a rod of material of the tobacco processing industry.

The invention relates, in particular, to the field of rod formation and rod processing in the tobacco processing industry, i.e., the creation of endless cigarette rods and endless filter rods in rod making machines. For example, an endless cigarette rod is created by initially showering tobacco onto a rod conveyor, then enclosing the endless rod of tobacco with a strip of cigarette paper, and then cutting cigarettes of multiple use lengths from the endless rod of tobacco. Forming the endless rod of tobacco or endless filters and the subsequently cutting, or cutting to length, of the rod occurs at high speed. With present day cigarette and filter manufacturing machines, rod speeds are typically 10 m/s, such that, with section lengths of 100 mm, there are 100 cutting cycles per second.

2. Discussion of Background Information

The quality of the cigarettes depends on the state of the tobacco in the endless tobacco rod. For this reason, the moisture and the density of the tobacco in the endless cigarette rod are measured, and the density, in particular, is controlled. Furthermore, the case of sudden or transient signal fluctuations suggests the presence of foreign bodies, wherein the corresponding rod sections are subsequently sorted out.

In modern cigarette manufacturing machines, this occurs using microwave measurement devices that have at least one microwave resonator housing, through which the endless rod of tobacco passes, as is disclosed in the document DE 10 2004 017 597 B4 (and in counterpart U.S. Publication No. 2005/0225332), for example, the disclosures of which are expressly incorporated by reference herein in their entireties. That document discloses a resonator housing with a resonator cavity in the form of a hollow cylinder that is disposed symmetrically to the endless cigarette rod. It provides a coupling in antenna and a coupling out antenna, using which a microwave signal is coupled in the resonator cavity for inducing an oscillation, and a transmitted part is coupled out in turn.

The measurement using a microwave resonator utilizes the physical fact that the resonance curve of the microwave field in the microwave resonator changes with the presence of a rod of material in the microwave resonator. In principle, the complex dielectric constant of the rod of material guided through the resonator is measured. The complex dielectric constant has a real part and an imaginary part, or a magnitude and a phase. The information about the density and the moisture content of the rod are contained in the two parameters of the complex dielectric constant. Changes in the density or moisture content lead to the characteristic change of the two parameters, and with it, to the resonance curve of the microwave resonator.

Compared to the unloaded microwave resonator, the maximum or minimum of a resonance curve shifts to lower frequencies in the presence of a rod of material. In addition, the resonance curve broadens. Changes in the density and changes in the moisture of the rod of material respectively create their own specific changes of the position, height and width of the resonance curve. If at least two measurement variables of the resonance curve are measured, the density and the moisture can be determined independent of each other within the scope of the measurement accuracy and of the correlations of the functional dependencies of the measurement variables from the rod density and rod moisture.

An evaluation circuit for evaluating a microwave resonator-measurement signal is known from the document EP 0 791 823 A2 (and its counterpart U.S. Pat. No. 6,163,158), the disclosures of which are expressly incorporated by reference herein in their entireties. Multiple independent measurement variables are created, in that microwaves with at least two different frequencies, with which a part of the resonance curve is sampled, are supplied to the resonator. Shifts of the resonance are captured by comparison of the resonance curves of the resonator influenced by the material and uninfluenced by material, and the damping is captured by comparison of the amplitudes of the resonator curves at the frequencies of the supplied microwaves. The density and the moisture of the endless rod of tobacco are reconstructed from the amplitude of the measured signals and the gradient of the slope.

The fundamental frequency of the microwave signal is adjusted with respect to the resonance curve for the unloaded microwave resonator so that it is located at the inflection point of one of the slopes of the resonance curve. The at least two modulated frequencies lie above and below the inflection point on the same slope. In a numerical example, 5.79 GHz and 5.81 GHz, that is 5.8 GHz ±10 MHz, are named as input frequencies. Switching between the two frequencies occurs every 5 μs, i.e., a frequency of 100 kHz. The microwave output signal is rectified via a circulator and a microwave diode, and further led via an analog to digital converter to an evaluation arrangement.

In practice, this procedure is limited. For measuring on a slope of a resonance curve the measurement is performed at a fixed working frequency, preferably at the point of inflection of the slope of the resonance of the unloaded resonator. In the case of comparatively small quantities of material in the resonator, only small signal changes are observed, whereas with large quantities of material, there are large changes of the signal, which can also lead to oversteering the signal. Small signal changes imply poor accuracy of the measurement and poor discrimination of the rod density and moisture. Therefore, the occurring small signal changes with which the system must still function reliably, represent a high demand for accuracy on the microwave signal processing. Due to this high demand, all components must be produced and assembled with very high accuracy, which results in correspondingly high costs.

Also, due to the small signal changes, small changes or drifts of the characteristic values of the microwave circuit components, which can arise due to component aging or temperature fluctuations and other external changes for example, impact the measurement accuracy. Consequently, the exact calibration of the system must be checked frequently, and if necessary, must be repeated.

With the known measurement method, the microwave signals must be rectified. This is performed using microwave diodes, in particular, Schottky diodes. These diodes have individual non-linear and temperature dependent characteristic curves which cause systematic measurement inaccuracies that can be only partially corrected based on temperature measurements. This fact limits the measurement accuracy and requires an individual compensation.

Independent of this, with measurements using a microwave resonator outside of the resonance frequency it must be observed that the shape of the electrical field used for the measurement is not aligned ideally axially outside of the resonance frequency, but rather diagonally in the resonator, and in the shape of the field is also dependent on the fill level, rod density and rod moisture. Consequently, the measurement accuracy is position dependent. For foreign body detection based on the microwave measurement, the reliability of detecting foreign bodies possibly present in the rod of material therefore depends on the position in the rod.

### SUMMARY OF THE EMBODIMENTS

Therefore, in contrast to the prior art, embodiments of the present invention are directed to a device, a measurement device, and a method for processing and measuring properties of a rod of material of the tobacco processing industry that is moved or moving along its longitudinal axis at high speed, with which the previously stated accuracy requirements can be maintained better than before.

According to embodiments, a device for processing and measuring properties of a moved or moving rod of material, particularly moved or moving along the longitudinal axis, of the tobacco processing industry, can include a microwave measurement device, which has a microwave resonator through which the endless rod of material is conveyed or can be conveyed. On an input side, the microwave resonator is supplied or can be supplied with a measurement signal, generated by a microwave generator, having an output frequency f₀. The measurement device is further developed in that at least one analysis arrangement is provided that includes a connection in series of a mixer, a low-pass filter, and an analog to digital converter. The mixer is connected to a port of the microwave resonator and to an output of a local oscillator and is designed to generate a difference signal of a frequency f_{IM} through mixing the measurement signal of frequency f₀, transmitted or reflected by the microwave resonator, and a signal of a local frequency f_{LO} generated by the local oscillator, where f_{IM} is less than f₀ and corresponds to the value of the difference of the frequencies f₀ and f_{LO}. The low-pass filter is designed to pass an output signal of the mixer with the intermediate frequency f_{IM}, and to filter out higher frequency signal portions.

The invention is based on the fundamental idea that in the device according to the invention, using a heterodyne method, the reflected or transmitted measurement signal is modulated down to the intermediate frequency f_{IM} while maintaining amplitude and phase. The intermediate frequency f_{IM} is not within the microwave range, rather it has a substantially lower frequency, in particular between 1 MHz and 100 MHz, preferably between 5 and 20 MHz. This signal, in contrast to the microwave signal which has a frequency of approximately 6 GHz for example, can be fed directly to the analog to digital conversion with available fast A/D converters so that nonlinearities of analog components such as those generated by a microwave diode, are avoided. Due to the correspondingly larger signal amplitude, drift and tolerance influences are minimized and, therefore, cycle times between system checks and recalibrations are increased.

The processing of the rod of material can be the production of an endless cigarette rod or an endless filter rod, the addition of additives, wrapping the rod with a wrapping paper and/or cutting cigarettes or filter plugs for example, or even producing a rod from textile fibers and the stretching of the rod. The measurement results can be used for the purpose of controlling the production process and/or the processing process so that a uniform rod density and rod moisture are attained, or so that parts of the rod, whose density or moisture lie outside of specified parameters are eliminated from the further processing.

The resonance behavior of the resonator can be measured in a reflection arrangement in which only one port at the resonator is used for coupling in a microwave signal and for the measurement, or in a transmission arrangement in which one port is used at the microwave resonator for coupling in and a further port is used for the measurement of the transmitted signal. In microwave technology, the transmission and reflection behavior of resonators is described by scattering parameters, the so-called “S parameters”. With these, the S₁₁ parameter describes the reflection at the input port of the resonator depending on the frequency, and the S₂₁ parameter describes the transmission properties from the input port to the output port. Both S parameters are complex value functions of the frequency and of the complex value dielectric constant of the rod. The S parameters can be represented as a real part and an imaginary part, or as a magnitude and phase. In the latter named case, changes in the density or moisture content of the rod cause changes of the magnitude and phase of the S parameters of the resonator.

In the heterodyne modulation method used according to the invention, a frequency mixture of signals that is composed of the fundamental frequency f₀ and the sidebands f₀+f_{LO} as the upper sideband and |f₀−f_{LO}| as the lower sideband is created by mixing a harmonic microwave oscillation f₀ with a low frequency harmonic local oscillator signal f_{LO}. Because the local oscillator signal is shifted only by a small value, namely the intermediate frequency ±f_{IM}, relative to the output signal f₀, the two sidebands have the frequencies 2fₒ±f_{IM} and f_{IM}. Due to low-pass filtering, only the signal with the frequency f_{IM} still remains from the frequency mixture.

Preferably, at least two analysis arrangements, in particular of the same kind, are provided, each with a connection in series including at least one mixer, a low-pass filter and an analog to digital converter. One analysis arrangement receives a measurement signal transmitted by the microwave resonator and the other analysis arrangement receives a measurement signal reflected by the microwave resonator. In this manner, in particular by way of the same type of analysis arrangements, both the S₂₁ as well as the S₁₁ parameters can be measured using the heterodyne modulation method used according to the invention. The large number of measurement values permits a further increase of the accuracy for determining the density and moisture of the rod of material.

Both analysis arrangements are preferably led to a downstream common evaluation device.

An insulator, a circulator, a directional coupler and/or another signal divider are advantageously disposed between the microwave generator and the microwave resonator. These components prevent, among others, the disruption of the generator by reflected microwave power.

If advantageously a further analysis arrangement is provided, in particular of the same type, with a connection in series including a mixer, a low-pass filter and an analog to digital converter, that receives a decoupled part of the output signal of the frequency f₀ via the input-side disposed insulator, circulator directional coupler and/or another signal divider. A signal is available with which it is possible to directly compare the input and output signals according to the magnitude and phase, in particular, by a downstream common evaluation device. In addition, drift in the amplitude and/or the phase of the output signal can thereby be compensated.

Preferably, the analysis arrangements with the connections in series are of the same kind in each case, so that direct comparisons are possible. Of the same kind means, in particular, that the low-pass filters have the same filter characteristics and the analog to digital converters are matched to each other, in particular, their threshold values and dynamic ranges and factors.

Preferably, a phase detector and a control device connected to the phase detector are provided. The phase detector receives the output signal of the low-pass filter of the analysis arrangement that receives the part of output signal of the frequency f₀ that was decoupled on the input side of the insulator or circulator. The control device is designed to control the local frequency f_{LO} of the local oscillator so that a phase difference between the intermediate frequency signal of the frequency f_{IM} and an externally supplied clock signal of frequency f_{clock} is equal to zero. In this manner, a readjustment of the local frequency f_{LO}, to an output signal f₀, possibly with drift, is possible so that neither frequency changes nor phase changes of the output signal lead to drift in the intermediate frequency f_{IM} that is significant for the subsequent digitization. Thereby, the measurement is stable and largely independent of external influences.

In an advantageous further development, a control unit is provided for tracking the output frequency f₀ according to the present resonant frequency in the microwave resonator. The tracking of the output frequency f₀, which is supplied to the microwave resonator, according to the present resonance frequency in the microwave resonator has several advantages. Thus, at resonance, the shape of the electrical field used for the measurement is ideally aligned axially so that the measurement accuracy is no longer dependent on the location or position. Therefore, foreign bodies in the rod for example, can be easily detected independent of their position. Furthermore, the microwave amplitude of the transmitted signal is maximal at resonance for any arbitrary attenuation in the resonator. In this way, error influences due to component influences are minimized. A further advantage consists in that processing can be performed over greater measurement ranges without system conversion.

Because the control unit carries out frequency tracking based on the measured values of the analog to digital to converter arriving in real time, a quasi-continuous and quasi-instantaneous frequency tracking is possible that also has a minimum time delay.

In a preferred embodiment, the control unit is designed to use the value of the phase and/or the amplitude of the transmitted or reflected signal as a controlled variable, wherein a value of the phase equal to zero and/or an amplitude maximum or an amplitude minimum is aimed for. At resonance, the phases of both transmitted signals as well as the reflected signals have a zero crossing. In the presence of a rod of material in the resonator, the frequency response curves of both phases are largely linear around the zero crossing. For this reason, the phases or the zero crossings of the phases are well-suited as control variables for the frequency tracking. The information about the phase is available in fractions of a millisecond so that a tracking of the frequency coupled into the microwave resonator after the resonance frequency occurs quasi-instantaneously. In this space of time, an endless rod of tobacco is further moved only by a fraction of a millimeter.

Advantageously, an evaluation device for evaluating the output signals of the analog to digital converter(s) is provided. In particular, the evaluation device is integrated into a microprocessor or into the control device. Preferably, the evaluation device is downstream and common to the analog to digital converters.

Embodiments of the invention are directed to a microwave measurement device for a device for processing and measuring properties of a moved or moving rod of material, particularly moved or moving at high speed along the longitudinal axis, of the tobacco processing industry, as described above. The device includes a microwave resonator through which the endless rod of material can be conveyed. On the input side, the microwave resonator is supplied or can be supplied with a measurement signal generated by a microwave generator having an output frequency f₀. The microwave measurement device is further developed in that at least one analysis arrangement is provided that includes a connection in series of a mixer, a low-pass filter and an analog to digital converter. The mixer is connected to a port of the microwave resonator and to an output of a local oscillator and is designed to generate a difference signal of a frequency f_{IM} through mixing the measurement signal of frequency f₀, transmitted or reflected by the microwave resonator, and a signal of a local frequency f_{LO} generated by the local oscillator, in which f_{IM} is less than f₀ and corresponds to the value of the difference of the frequencies f₀ and f_{LO}. The low-pass filter is designed to pass an output signal of the mixer with the intermediate frequency f_{IM} and to filter out higher frequency signal portions.

The microwave measurement device has same properties, features and advantages as the previously described device according to the invention.

Finally, embodiments of the invention are directed to a method for processing and measuring properties of a rod of material of the tobacco processing industry, that is conveyed through a microwave resonator. A measurement signal is generated with an output frequency f₀, and is supplied into a microwave resonator, that is further developed in that a mixed signal is generated by mixing the measurement signal of frequency f₀ transmitted or reflected by the microwave resonator and a signal of a local frequency f_{LO} generated by a local oscillator, said mixed signal having a portion with an intermediate frequency f_{IM} that is less than f₀ and corresponding to the value of the difference of the frequencies f₀ and f_{LO}, wherein in a low-pass filter the intermediate frequency portion of the mixed signal is passed to an analog to digital converter, whereas higher frequency portions of the mixed signal are filtered out.

This embodiment corresponds to the method, based on a heterodyne modulation method, performed in the device according to the invention and the measurement device according to the invention. The method according to the invention also offers the advantages according to the invention, in particular independence from non-linear characteristic curves of analog components, such as Schottky diodes, and insensitivity resulting therefrom with respect to the accuracy of small signal amplitudes. The method according to the invention yields the data from which the scattering parameters S₁₁ and/or S₂₁ are measured in amplitude and/or phase or real part and/or imaginary part. Amplitudes and phases are contained in a signal of the comparatively low intermediate frequency f_{IM} which is accessible to processing by a direct analog to digital conversion so that the digital output values already contain the necessary information about amplitude and phase.

Preferably, by mixing with the local frequency f_{LO} an output signal of frequency f₀, in particular shielded from the microwave resonator by an insulator, a circulator, a directional coupler and/or another signal divider is modulated down to the intermediate frequency f_{IM} and transmitted via a low-pass filter to an analog to digital converter. This means that the output signal that is not disrupted by signal parts reflected by the microwave resonator is present digitally as a direct reference value, and serves as a comparison value for the measurement signals of the reflected and/or transmitted signals. In the process, at the location at which the output signal is tapped, the signal is shielded from reflected signals by the insulator or circulator.

Preferably, the analog to digital converter(s) and/or the oscillator that generates the output signal of the frequency f₀ and/or the local oscillator are synchronized to a frequency stabilized time signal. This has the consequence that the phase position of the sampling of the output signal modulated down to the intermediate frequency f_{IM} is synchronized to its phase so that at any time the phase of the signal can be determined with high accuracy. Incorrect measurements of the phase due to phase shifts between the generation of the intermediate frequency f_{IM} and sampling are therefore excluded.

The local frequency of the local oscillator is advantageously controlled via a phase detector and a control device so that there is no phase difference between the intermediate frequency signal of the frequency f_{IM} and an externally supplied clock signal f_{clock}. This results in a digitizable signal of the intermediate frequency f_{IM} with constant frequency and a phase position that does not depend on the relative phase shift between the output signal f₀ and the local oscillator signal f_{LO}, but only on the phase shift in the microwave resonator.

In a preferred further development, it is provided that a control of the output frequency f₀ is carried out to a present resonance frequency in the microwave resonator. In a preferred alternative, the control is carried out using a phase of the transmitted signal, where by adapting the output frequency f₀ a phase value of zero, in particular, is aimed for. This corresponds to the control already described above, based on the zero crossing of the phase progression of the S₁₁ component or the S₂₁ component. This alternative is very accurate and very fast.

Alternatively, it is provided that the control is carried out using the position of a maximum or minimum of a transmitted and/or reflected signal, where the output frequency is switched periodically between two values which are adapted so that the output frequency f₀ lies alternatingly above and below the resonance maximum or minimum, where it is aimed for to attain the same signal amplitude for both frequencies.

The mixing with the tracked local oscillator signal f_{LO} then results in a signal with a constant frequency f_{IM}, which changes its amplitude and phase in cycle with the switching of the frequency f₀. The control variable in this case is a minimal and vanishing difference of the amplitude in the two cases. Because a drift of the resonance frequency leads to a characteristic difference between the amplitudes with the two frequencies, which is positive or negative, this control variable is also well-suited for tracking the excitation frequency according to the resonance frequency in the microwave resonator.

Alternatively, a value of zero for the slope of the resonance curve is also advantageously aimed for. An alternative control advantageously provides controlling to a maximum signal amplitude with a measurement of the S₂₁ parameter, and/or controlling to a minimum signal amplitude with a measurement of the S₁₁ parameter.

The devices, measurement devices, and methods according to the invention are advantageously applicable in environments other than in the tobacco processing industry, for instance, for spinning works preparation when cotton fibers and synthetic fibers are aligned and homogenized in parallel in carding machines and stretching devices.

Embodiments of the invention are directed to a device for processing and measuring properties of a moving rod of material of the tobacco processing industry. The device includes a microwave measurement device having a microwave resonator structured and arranged so that the endless rod of material is conveyable through the microwave resonator from an input side to an output side, and a microwave generator is structured to generate a measurement signal having an output frequency f₀ and arranged to supply the measurement signal to the input side of the microwave resonator. The device also includes at least one analysis arrangement including a mixer, a low pass filter, and an analog to digital converter arranged in series, and a local oscillator structured to generate a signal with a local frequency of f_{LO}. The mixer is connected to a port of the microwave resonator and to an output of the local oscillator, and is structured to generate a difference signal of a frequency f_{IM} by mixing the measurement signal of frequency f₀, which is one of transmitted or reflected by the microwave resonator, and the signal of the local frequency f_{LO}. Frequency f_{IM} is less than f₀ and corresponds to a value of the difference of the frequencies f₀ and f_{LO}, and the low-pass filter is structured to pass an output signal of the mixer with the intermediate frequency f_{IM}, and to filter out higher frequency signal portions.

According to embodiments of the instant invention, the at least one analysis arrangement can include at least two analysis arrangements, in which each of the at least two analysis arrangements include a mixer, a low-pass filter, and an analog to digital converter arranged in series. A first of the at least two analysis arrangements is structured and arranged to receive a measurement signal transmitted by the microwave resonator, and a second of the at least two analysis arrangements is structured and arranged to receive a measurement signal reflected by the microwave resonator.

In accordance with other embodiments of the invention, at least one of an insulator, a circulator, a directional coupler, and a signal divider may be disposed between the microwave generator and the microwave resonator. Another analysis arrangement can include a mixer, a low-pass filter, and an analog to digital converter arranged in series, such that the another analysis arrangement is structured and arranged to receive a decoupled part of the output signal of the frequency f₀ via the at least one of the circulator, the insulator, the directional coupler, and the signal divider. A phase detector and a control device can be connected to the phase detector, such that the phase detector may be arranged to receive the output signal of the low-pass filter of the another analysis arrangement, and the control device can be structured to control the local frequency f_{LO} of the local oscillator so that a phase difference between a mixed down intermediate frequency signal of the frequency f_{IM} and a clock signal of a frequency f_{clock} (is equal to zero.

In accordance with still other embodiments, a control device can be structured and arranged to track the output frequency f₀ according to a present resonance frequency in the microwave resonator. The control device can utilize as a control variable at least one of a phase value and an amplitude of the transmitted or reflected signal from the microwave resonator, so that a target for the control variable is at least one of a phase value of zero and an amplitude maximum or an amplitude minimum.

According to other embodiments, an evaluation device may be structured and arranged to evaluate output signals of the analog to digital converter.

Further, the control device may include an evaluation device structured and arranged to evaluate output signals of the analog to digital converter.

Embodiments of the invention are directed to a microwave measurement device for a device for processing and measuring properties of a moving rod of material of the tobacco processing industry, as described above. The microwave measurement device includes a microwave resonator structured and arranged so that the endless rod of material is conveyable through the microwave resonator, a microwave generator structured to generate a measurement signal having an output frequency f₀ and arranged to supply the measurement signal to an input side the microwave resonator, and at least one analysis arrangement comprising a mixer, a low-pass filter, and an analog to digital converter, and a local oscillator structured to generate a signal of a local frequency f_{LO}. The mixer is structured to be connectable to a port of the microwave resonator and to an output of a local oscillator and is arranged to generate a difference signal of a frequency f_{IM} by mixing the measurement signal of frequency f₀, which is one of transmitted or reflected by the microwave resonator, and the signal of the local frequency f_{LO}. Frequency f_{IM} is less than f₀ and corresponds to a value of a difference of the frequencies f₀ and f_{LO}, and the low-pass filter is structured to pass an output signal of the mixer with the intermediate frequency f_{IM}, and to filter out higher frequency signal portions.

Embodiments of the instant invention are directed to a method for processing and measuring properties of a rod of material of the tobacco processing industry. The method includes conveying the rod of material through a microwave resonator, generating a measurement signal with an output frequency f₀ and supplying the measurement signal to a microwave resonator, and generating a mixed signal by mixing the measurement signal of frequency f₀, which is one of transmitted or reflected by the microwave resonator, and a signal of a local frequency f_{LO} generated by a local oscillator, wherein the mixed signal includes a portion with an intermediate frequency f_{IM} that is less than f₀ and corresponds to the value of a difference of the frequencies f₀ and f_{LO}. The method also includes passing the intermediate frequency portion of the mixed signal via a low-pass filter to an analog to digital converter, and filtering out higher frequency portions.

According to embodiments of the invention, the method can further include, via a mixing with the local frequency f_{LO}, modulating the output signal of the frequency f0, shielded from the microwave resonator through at least one of an insulator, a circulator, a directional coupler, and a signal divider, down to the intermediate frequency f_{IM}, which is then transferred via a second low-pass filter to a second analog to digital converter.

In accordance with still yet other embodiments of the present invention, the method can further include controlling the local frequency of the local oscillator by one of a phase detector or a control device so that a phase difference between the intermediate frequency signal of the frequency f_{IM} and an externally supplied clock signal f_{clock} is zero. The method may also include controlling the output frequency f₀ to a present resonance frequency in the microwave resonator. The controlling utilizes a phase of the transmitted or reflected signal, and a target phase value is zero. Further, the controlling can utilize a position of a maximum or a minimum of at least one of the transmitted and reflected signal, and the method may further include periodically switching the output frequency f₀ between two values that are adapted so that the output frequency alternatingly lies above and below the resonance maximum or minimum, wherein a same signal amplitude at both frequencies is sought. The controlling can utilize the maximum of the minimum of the at least one of the transmitted and reflected signal, and the method may further include finding a value of the slope of a resonance curve of zero via the adaptation of the output frequency f₀. Moreover, the method can further include at least one of: with a measurement of an S₂₁ parameter, controlling a maximum signal amplitude, and with a measurement of the S₁₁ parameter, controlling a minimum signal amplitude.

Other exemplary embodiments and advantages of the present invention may be ascertained by reviewing the present disclosure and the accompanying drawing.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 illustrates the schematic design of a cigarette rod machine;

FIG. 2 illustrates a schematic cross-sectional representation through a microwave resonator;

FIG. 3 illustrates the frequency-response curves of the amplitudes of the scattering parameters S₂₁ and S₁₁ in the cases of a filled and unfilled resonator;

FIG. 4 illustrates the frequency-response curves of the phases of the scattering parameters S₂₁ and S₁₁ in the cases of a filled and unfilled resonator;

FIG. 5 illustrates a schematic circuit arrangement of a measurement device according to the invention;

FIG. 6 illustrates a schematic circuit arrangement of a further measurement device according to the invention; and

FIG. 7 illustrates a schematic circuit arrangement of a further measurement device according to the invention with frequency tracking.

### DETAILED DESCRIPTION OF THE EMBODIMENTS

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

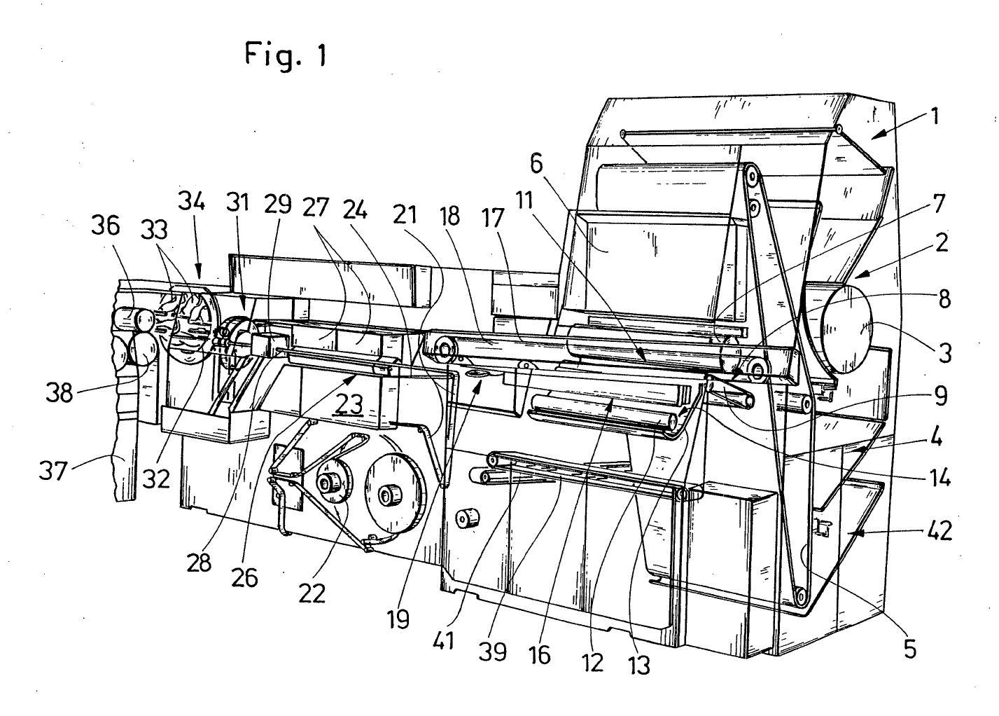

FIG. 1 illustrates the general design of a cigarette rod machine of the “PROTOS” type by Hauni Maschinenbau AG of Hamburg, Germany. A predistributor 2 is loaded in portions with loose tobacco from a sluice 1. Under control, a take-out roll 3 of the predistributor 2 replenishes a tank 4 with tobacco from which a steep-angle conveyor 5, designed as an endless belt, removes tobacco and supplies a bulking chute 6. From the bulking chute 6, a pin roller 7 removes a uniform stream of tobacco, which is beaten out of the pins of the pin roller 7 by a picker roller 8, and flings it onto an apron 9 guided as an endless belt and circulating with constant speed.

A tobacco carpet formed on the apron 9 is flung into a sieving device 11 which generates an air curtain that larger or heavy tobacco parts pass by, whereas all other tobacco particles are directed by the air stream of the air curtain into a hopper 14 formed by a pin roller 12 and a wall 13. From the pin roller 12, the tobacco is flung into a tobacco channel 16 against a rod conveyor 17 at which the tobacco is held by suction air in a vacuum pressure chamber 18, and is showered as an endless tobacco rod. A trimmer 19 which is substantially composed of a pair of rotating discs disposed in the plane of the transport direction of the endless tobacco rod, and a deflector, removes excess tobacco from the endless tobacco rod and cuts the endless tobacco rod formed in this manner to the desired thickness.

Next, the tobacco rod is placed on an endless strip of cigarette paper 21, pulled from a reel 22, guided at the same speed and is guided through a printing unit 23. The endless strip of cigarette paper 21 is placed on a driven garniture belt 24 that transports the endless tobacco rod and the endless strip of cigarette paper 21 through a forming device 26 in which the endless strip of cigarette paper is folded around the endless rod of tobacco so that an edge stands up which is glued in a known manner by a glue apparatus, not shown. Thereupon, the adhesive seam is closed and dried by a tandem seam sealer 27.

An endless cigarette rod 28 formed in this manner passes through rod density measurement device 29 that controls the trimmer 19, and is cut by a knife apparatus 31 into double length cigarettes 32. These are transferred by a transfer device 34 having controlled arms 33 into a receiving drum 36 of a filter assembler 37, on whose cutting drum 38 they are divided into individual cigarettes using a circular knife. Endless conveyor belts 39, 41 convey excess tobacco into a container 42 disposed beneath the tank 4, from which the returned tobacco is removed again by the steep-angle conveyor 5.

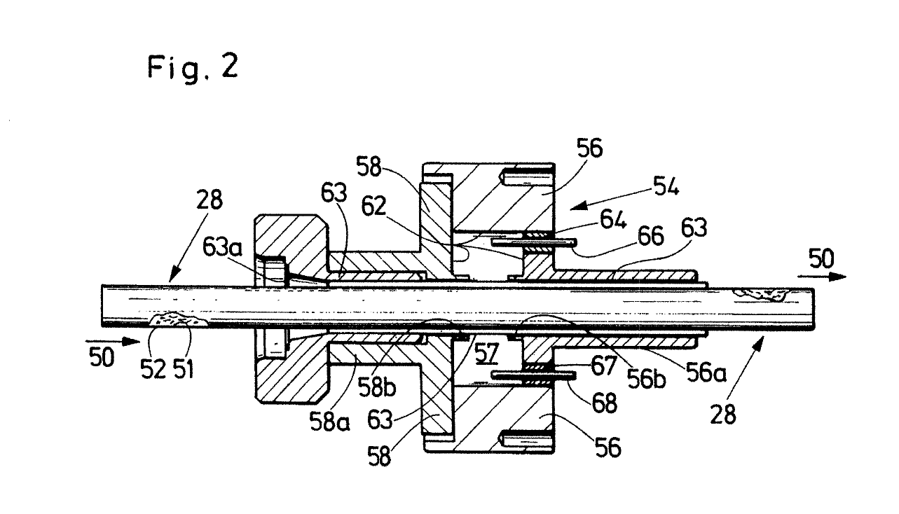

FIG. 2 shows a schematic cross-sectional representation of a suitable resonator housing. An endless cigarette rod 28, partially broken open, moving in the direction of the arrow 50, consisting of a filler 51 and a wrapper 52 of cigarette paper, passes through the resonator housing 54, to which the microwaves are fed for the purpose of capturing at least one property of the filler 51, for example the mass or the moisture. The resonator housing 54 has a cavity in the shape of a hollow cylinder 56, whose interior or resonator cavity 57 is disposed symmetrically to the endless cigarette rod 28. For closing, a cover 58 is screwed to it.

The resonator cavity 57 of the resonator housing 54 can be vapor coated with a thin layer of gold 62, which reliably prevents the formation of corrosion that would adversely influence the measurement value consistency, and simultaneously, because good electrical conduction, limits a damaging skin effect.

A protective pipe 63 that is preferably composed of a substance of the polyaryletherketone (PAEK) group, for example polyether ether ketone (PEEK), is used for mechanically closing the resonator cavity 57 with respect to the endless cigarette rod 28, and to prevent contamination of the resonator cavity 57. The protective pipe 63 is widened in the shape of a funnel at one of its ends 63a, at which the endless rod 28 enters into the resonator housing 54.

Outside of the resonator cavity 57, the resonator housing 54 extends in a tubular shape (56a, 58a) outwards on both sides in the direction of the rod 28, in order to prevent the emission of microwaves from the resonator cavity 57. It also extends in a tubular shape (56b, 58b) inwards to some extent. A coupling in antenna 66 insulated from the hollow cylinder 56 by an insulating ring 64 serves for coupling in the microwaves generated by a microwave generator. A coupling out antenna 68 insulated from the hollow cylinder 56 by an insulator 67 serves to decouple microwaves which are to be supplied to an evaluation circuit, not shown.

The frequency of the introduced microwave signal is preferably selected so that at resonance the amplitude of the microwave field in the cavity 57 has a maximum in the center, i.e. at the location of the endless cigarette rod 28. If the introduced frequency does not correspond to the resonance frequency, the amplitude has a maximum at the location of a coupling in antenna 66 and decreases in the direction of the coupling out antenna 68. In the process, the amplitude of the field decreases over the cross-section of the endless cigarette rod 28, that is, it is inhomogeneous.

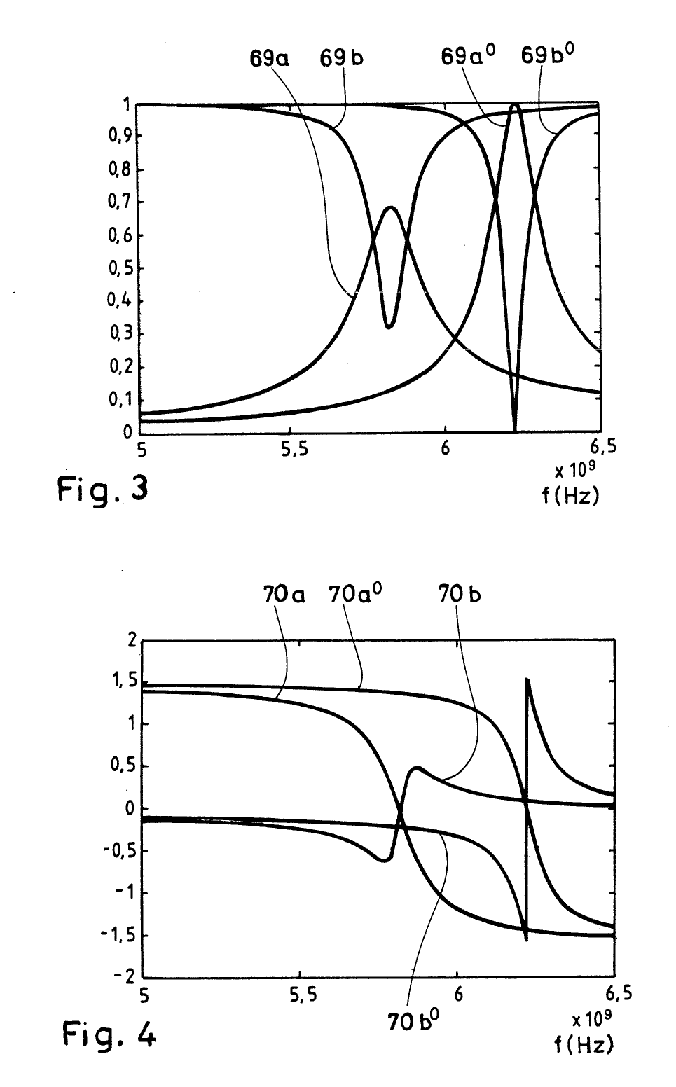

FIGS. 3 and 4 show the amplitudes and the phases of the scattering parameters S₁₁ and S₂₁ of an ideal loss-free resonator in a simulation. The X-axes represent the frequency of the introduced microwave signal and extend between 5 GHz and 6.5 GHz. The self-damping of the unswitched or empty resonator is assumed to be zero in the simulation.

FIG. 3 shows, on the Y-axis, the relative amplitude with values between 0 and 1. Curves with the reference numbers 69a⁰ and 69b⁰ correspond to the unloaded resonator. Here, 69a⁰ represents the progression of the frequency-dependent transmitted component, thus, the S₂₁ parameter which has a maximum value of 1 at approximately 6.23 GHz. Thus, complete transmission prevails at this frequency. The corresponding reflection curve for the scattering parameter S₁₁, in the case of an unloaded resonator, with the reference number 69b⁰, has a minimum with the value 0 at this frequency. Outside of this minimum, the parameter S₁₁ has a value near 1, therefore, nearly complete reflection prevails.

If the resonator is penetrated by an endless rod of material, for example an endless cigarette rod 28, the resonance frequency shifts to a lower frequency, to approximately 5.8 GHz in the represented example. This applies for both the S₂₁ parameter 69a as well as for the S₁₁ parameter 69b. At the same time, the two resonance curves broaden. In addition, the amplitude of S₂₁ decreases at resonance, while the amplitude of S₁₁ increases. Thus, the curve of the S₂₁ parameter only attains a maximum of approximately 0.7, whereas the reflection, i.e. the S₁₁ parameter, increases to 0.3 at resonance.

It is not shown that in the loss-free case, i.e. the case without material in the resonator, the variable (|S₁₁|²+|S₂₁|²)^{0.5} has the value 1 in the entire frequency range, whereas in the lossy case it has a value of less than 1 at resonance, where the minimum is attained at the resonance frequency. The difference to 1 is a measure for the power dissipation realized in the resonator. This value is always at a maximum at resonance.

FIG. 4 shows the frequency-response curves of the phases of the resonance curves represented in FIG. 3 in the loaded and unloaded state. In the unloaded state, the phase 70a⁰ of the S₂₁ parameter, which at lower frequencies starts with the value π/2, has a zero crossing at 6.23 GHz, while converging at higher frequencies towards the value −π/2. The corresponding S₁₁ phase parameter 70b⁰ starts at a low negative value and approaches the resonance frequency so that its value decreases towards −π/2. When crossing the resonance frequency the phase reverses and increases to the value +π/2. At still higher frequencies, the value decreases towards 0. With this, an ideal microwave resonator is assumed without any losses.

In the case of a loaded microwave resonator, a phase 70a of the S₂₁ parameters results whose zero crossing is shifted with respect to the unloaded case 70a⁰ towards a lower resonance frequency of approximately 5.8 GHz. Furthermore, the slope of the zero crossing is somewhat reduced. The phase 70b of the S₁₁ parameter is significantly changed compared to the unloaded case due to the broadening of the resonance and due to the loss in the resonator with the presence of an endless rod of material. In this case also, the S₁₁ phase parameter 70b starts initially at lower frequencies with a slightly negative value, and upon nearing the resonance frequency takes on a strongly negative value. However, there is no reversal at the value −π/2 toward +π/2, rather a zero crossing occurs with a positive slope. Shortly after crossing through the zero line, the phase 70b of the S₁₁ parameter increases in the loaded case to a positive maximum at approximately 0.5, and then reverses and at high frequencies again trends towards 0. The zero crossings of the phase 70a of the S₂₁ parameter and the phase 70b of the S₁₁ parameter in the immediate the vicinity of the zero crossings are well-suited as a control variable for frequency tracking.

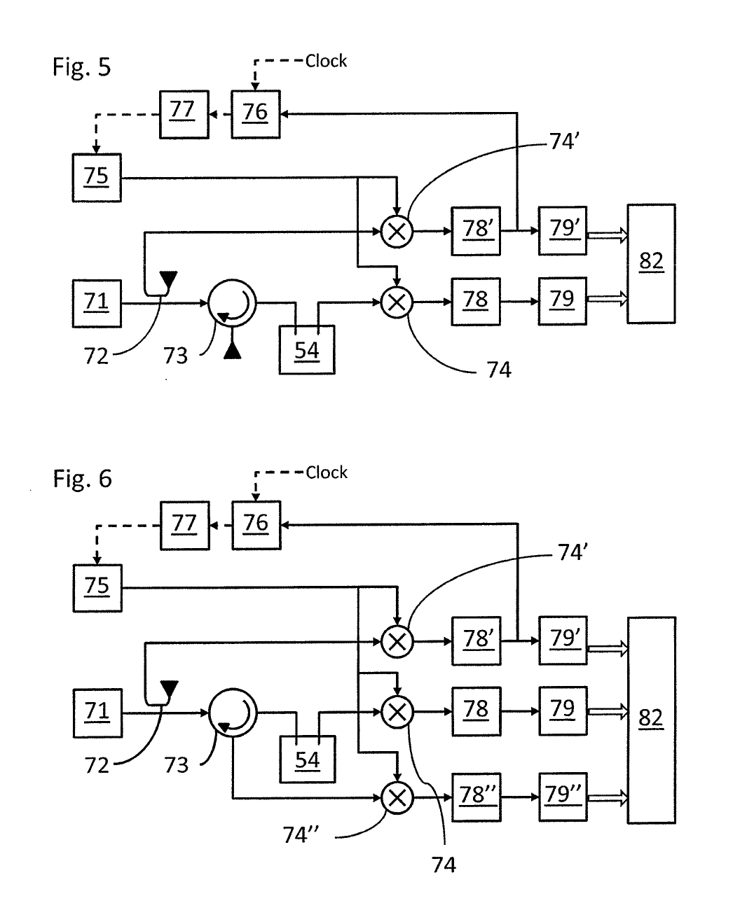

FIG. 5 shows a first example of a circuit arrangement according to the invention for implementing a heterodyne modulation method. In a synthesizer or microwave generator 71, a microwave signal with a frequency f₀, of approximately 6 GHz for example, is generated as an output signal. In a coupler 72, the signal is divided into two signals. One of the signals is led via an insulator or circulator 73, or a part of circuit that is functionally similar, to an input port of the microwave resonator 54. The signal transmitted in the microwave resonator 54 is tapped at an output port of the microwave resonator 54 and is supplied to a mixer 74, in which the transmitted signal is mixed with a local oscillator signal of a local oscillator 75. The local oscillator signal has a frequency f_{LO}, which lies slightly below, e.g., 10 MHz below, the output signal f₀.

By mixing the two signals f₀ at approximately 6 GHz and f_{LO} at approximately 5.99 GHz or 6.01 GHz, the mixer 74 generates two side bands with the frequencies 11.99 GHz or 12.01 GHz on the one side, and 10 MHz on the other. This frequency mixture is led to a low-pass filter 78, which now only passes the signal of the intermediate frequency f_{IM}, which in the present example is 10 MHz, to an analog to digital converter 79.

FIG. 5 also shows that the circulator 73 has a third port that is terminated by a load resistor symbolized by a triangle. That means that signals reflected by the input port of the microwave resonator 54 are not returned to the microwave generator 71, thereby disrupting it, but rather, are absorbed completely in the load. Therefore, the microwave generator 71 is completely shielded from reflected signals.

Directly at the output of the microwave generator 71 and at the input of the circulator 73, the output signal f₀ is partially decoupled and fed to a mixer 74′ which has as its second input the same local oscillator signal f_{LO} of the local oscillator 75, as the first mixer 74. The mixed signal of the mixer 74′ is passed through a low-pass filter 78′ to an analog to digital converter 79′. Therefore, the data from the analog to digital converters 79, 79′ provide information about the amplitude and the phase of the signal transmitted through the microwave resonator 64 as well as the undisturbed signal f₀, so that a very accurate determination of the amplitude and phase of the scatter parameter S₂₁ is possible. These signals are also fed to the evaluation device 82 that, for instance, determines the moisture and/or the density of the endless rod.

For stabilizing the intermediate frequency signal f_{IM}, a control circuit, or a phase locked loop (PLL) is provided that has a phase detector 76 and a control device 77 synchronized to a “clock”-signal. The phase detector determines phase shifts between the intermediate frequency signal f_{IM} and the timing signal f_{clock}, while the control device 77, which can also be called a loop filter, uses this phase shift to adapt the frequency of the local oscillator 75 via a transmission function, so that the phase shift is reverted to zero, or maintained at zero. Measured phase shifts in the analog to digital converter 79 therefore originate exclusively from phase shifts in the microwave resonator 54. Using the phase feedback and the frequency control of the local oscillator signal, frequency shifts of the output signal f₀ of the local oscillator 75 are also tracked.

The control and synchronization lines are shown as dashed lines in FIG. 5.

The mixing of the signals with the frequencies f₀ and f_{LO} has the effect that the output signal of the intermediate frequency f_{IM} contains the amplitude as well as the phase of the transmitted signal from the microwave resonator 54. Therefore, the intermediate frequency signal f_{IM}, that is digitized, contains the amplitude as well as the phase of the scattering parameter S₂₁ (see FIGS. 3 and 4). The parameter S₂₁ can be determined in magnitude and phase using the sampling circuit in FIG. 5, which is synchronized with reference to the external clock signal.

FIG. 6 shows a further circuit arrangement according to the invention, where now two analysis arrangements are shown having connections in series of mixer, low-pass filter and analog to digital converter. Differing from FIG. 5, where only the transmitted signal is subjected to a corresponding mixing, filtering and digitization, in accordance with the embodiment of FIG. 6, the signal reflected by the microwave resonator 54 is also decoupled in the circulator 73 at the third port, and a corresponding mixing, low-pass filtering, and digitization is applied to it. For this purpose, the mixer 74″ receives the same local oscillator signal of the local oscillator 75, as already received by the mixers 74 and 74′. The mixer 74″ is followed by the low pass filter 78″ and the analog-to-digital converter 79″. This way, not only the signal containing the amplitude and phase of the scatter parameter S₂₁ can be compared to the generating signal, but also a signal that contains the amplitude and phase of the scatter parameter S₁₁. The redundancy of the measurement obtained leads to a further improvement of the accuracy of the measurement of the density and moisture in an endless rod of material.

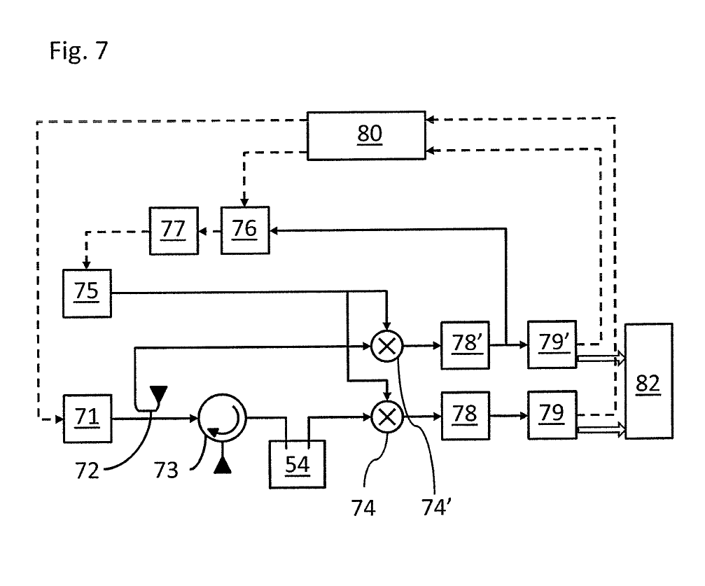

FIG. 7 shows a further development of the circuit arrangement according to FIG. 5. In addition to the components represented in FIG. 5, a control unit is provided in the form of a microprocessor 80 designed in particular as a digital signal processor, that receives the digitized measurement values determined by the analog to digital converters 79 and 79′. Because the microprocessor 80 contains all information about the phase position of the S₂₁ scattering parameter, the microprocessor 80 can control the microwave generator 71 and adapt its frequency f₀ so that phase position is controlled to the zero crossing of the phase of the S₂₁ scattering parameter. Therefore, the microwave signal supplied to the microwave resonator 54 is always at the present resonance. In addition, the microprocessor 80 generates a synchronization signal for the phase detector 76. This type of control is very fast and very accurate.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims. Further, all named features, including those taken from the drawings alone, and individual features, which are disclosed in combination with other features, are considered individually and in combination as essential to the invention. Embodiments according to the invention can be satisfied through individual characteristics or a combination of several characteristics.

### LIST OF REFERENCE SYMBOLS

1 sluice
2 predistributor
3 take-out roller
4 tank
5 steep-angle conveyor
6 bulking chute
7 pin roller
8 picker roller
9 apron
11 sieving device
12 pin roller
13 wall
14 hopper
16 tobacco channel
17 rod conveyor
18 vacuum pressure chamber
19 trimmer
21 endless strip of cigarette paper
22 reel
23 printing unit
24 garniture belt
26 forming device
27 tandem seam sealer
28 endless cigarette rod
29 rod density measurement device
31 knife apparatus
32 double length cigarettes
33 arm
34 transfer device
36 receiving drum
37 filter assembler
38 cutting drum
39 conveyor belt
41 conveyor belt
42 container
50 direction of movement
51 filler
52 wrapper
54 resonator housing
56 hollow cylinder
56a outer extension of the hollow cylinder 56
56b inner extension of the hollow cylinder 56
57 resonator cavity
58 cover
58a outer extension of the cover 58
58b inner extension of the cover 58
62 gold layer
63 protective pipe
63a protective pipe inlet
64 insulation ring
66 coupling in antenna
67 insulation
68 coupling out antenna
69a amount |S₂₁| of the loaded resonator housing
69a⁰ amount |S₂₁| of the unloaded resonator housing
69b amount |S₁₁| of the loaded resonator housing
69b⁰ amount |S₁₁| of the unloaded resonator housing
70a phase (S₂₁) of the loaded resonator housing
70a⁰ phase (S₂₁) of the unloaded resonator housing
70b phase (S₁₁) of the loaded resonator housing
70b⁰ phase (S₁₁) of the unloaded resonator housing
71 microwave generator
72 directional coupler
73 circulator
74, 74′, 74″ mixer
75 local oscillator
76 phase detector
77 control device
78, 78′, 78″ low-pass filter
79, 79′, 79″ analog to digital converter
80 closed loop control device
81 microprocessor
82 analysis device

What is claimed:

1. A device for processing and measuring properties of a moving rod of material of the tobacco processing industry, comprising
a microwave measurement device having a microwave resonator structured and arranged so that the endless rod of material is conveyable through the microwave resonator from an input side to an output side;
a microwave generator is structured to generate a measurement signal having an output frequency f₀ and arranged to supply the measurement signal to the input side of the microwave resonator;
at least one analysis arrangement comprising a mixer, a low pass filter, and an analog to digital converter arranged in series;
a local oscillator structured to generate a signal with a local frequency of f_{LO};
the mixer being connected to a port of the microwave resonator and to an output of the local oscillator, and being structured to generate a difference signal of a frequency f_{IM} by mixing the measurement signal of frequency f₀, which is one of transmitted or reflected by the microwave resonator, and the signal of the local frequency f_{LO};
wherein frequency f_{IM} is less than f₀ and corresponds to a value of the difference of the frequencies f₀ and f_{LO}, and
wherein the low-pass filter is structured to pass an output signal of the mixer with the intermediate frequency f_{IM}, and to filter out higher frequency signal portions.

2. The device according to claim 1, wherein the at least one analysis arrangement comprises at least two analysis arrangements, each of the at least two analysis arrangements comprising a mixer, a low-pass filter, and an analog to digital converter arranged in series,
wherein a first of the at least two analysis arrangements is structured and arranged to receive a measurement signal transmitted by the microwave resonator, and a second of the at least two analysis arrangements is structured and arranged to receive a measurement signal reflected by the microwave resonator.

3. The device according to claim 1, further comprising at least one of an insulator, a circulator, a directional coupler, and a signal divider being disposed between the microwave generator and the microwave resonator.

4. The device according to claim 3, further comprising another analysis arrangement comprising a mixer, a low-pass filter, and an analog to digital converter arranged in series,
wherein the another analysis arrangement is structured and arranged to receive a decoupled part of the output signal of the frequency f₀ via the at least one of the circulator, the insulator, the directional coupler, and the signal divider.

5. The device according to claim 4, further comprising a phase detector and a control device connected to the phase detector;
wherein the phase detector is arranged to receive the output signal of the low-pass filter of the another analysis arrangement,
wherein the control device is structured to control the local frequency f_{LO} of the local oscillator so that a phase difference between a mixed down intermediate frequency signal of the frequency f_{IM} and a clock signal of a frequency f_{clock} is equal to zero.

6. The device according to claim 1, further comprising a control device structured and arranged to track the output frequency f₀ according to a present resonance frequency in the microwave resonator.

7. The device according to claim 6, wherein the control device utilizes as a control variable at least one of a phase value and an amplitude of the transmitted or reflected signal from the microwave resonator, wherein a target for the control variable is at least one of a phase value of zero and an amplitude maximum or an amplitude minimum.

8. The device according to claim 1, further comprising an evaluation device structured and arranged to evaluate output signals of the analog to digital converter.

9. The device according to claim 6, wherein the control device comprises an evaluation device structured and arranged to evaluate output signals of the analog to digital converter.

10. A microwave measurement device for a device for processing and measuring properties of a moving rod of material of the tobacco processing industry, according to claim 1, comprising:
a microwave resonator structured and arranged so that the endless rod of material is conveyable through the microwave resonator;
a microwave generator structured to generate a measurement signal having an output frequency f₀ and arranged to supply the measurement signal to an input side the microwave resonator;
at least one analysis arrangement comprising a mixer, a low-pass filter, and an analog to digital converter;
a local oscillator structured to generate a signal of a local frequency f_{LO};
wherein the mixer is structured to be connectable to a port of the microwave resonator and to an output of a local oscillator and is arranged to generate a difference signal of a frequency f_{IM} by mixing the measurement signal of frequency f₀, which is one of transmitted or reflected by the microwave resonator, and the signal of the local frequency f_{LO};
wherein f_{IM} is less than f₀ and corresponds to a value of a difference of the frequencies f₀ and f_{LO}, and
wherein the low-pass filter is structured to pass an output signal of the mixer with the intermediate frequency f_{IM}, and to filter out higher frequency signal portions.

11. A method for processing and measuring properties of a rod of material of the tobacco processing industry, comprising:
conveying the rod of material through a microwave resonator;
generating a measurement signal with an output frequency f₀ and supplying the measurement signal to a microwave resonator;
generating a mixed signal by mixing the measurement signal of frequency f₀, which is one of transmitted or reflected by the microwave resonator, and a signal of a local frequency f_{LO} generated by a local oscillator, wherein the mixed signal includes a portion with an intermediate frequency f_{IM} that is less than f₀ and corresponds to the value of a difference of the frequencies f₀ and f_{LO};
passing the intermediate frequency portion of the mixed signal via a low-pass filter to an analog to digital converter, and filtering out higher frequency portions.

12. The method according to claim 11, further comprising, via a mixing with the local frequency f_{LO}, modulating the output signal of the frequency f₀, shielded from the microwave resonator through at least one of an insulator, a circulator, a directional coupler, and a signal divider, down to the intermediate frequency f_{IM}, which is then transferred via a second low-pass filter to a second analog to digital converter.

13. The method according to claim 11, further comprising controlling the local frequency of the local oscillator by one of a phase detector or a control device so that a phase difference between the intermediate frequency signal of the frequency f_{IM} and an externally supplied clock signal f_{clock} is zero.

14. The method according to claim 13, further comprising controlling the output frequency f₀ to a present resonance frequency in the microwave resonator.

15. The method according to claim 14, wherein the controlling utilizes a phase of the transmitted or reflected signal, and a target phase value is zero.

16. The method according to claim 13, wherein the controlling utilizes a position of a maximum or a minimum of at least one of the transmitted and reflected signal, and the method further comprises periodically switching the output frequency f₀ between two values that are adapted so that the output frequency alternatingly lies above and below the resonance maximum or minimum, wherein a same signal amplitude at both frequencies is sought.

17. The method according to claim 13, wherein the controlling utilizes the maximum of the minimum of the at least one of the transmitted and reflected signal, and the method further comprises:
finding a value of the slope of a resonance curve of zero via the adaptation of the output frequency f₀.

18. The method according to claim 13, wherein the method further comprises, at least one of
with a measurement of an S₂₁ parameter, controlling a maximum signal amplitude, and
with a measurement of the S₁₁ parameter, controlling a minimum signal amplitude.
